(19) United States
(12) Patent Application Publication
(10) Pub. No.: US 2026/0101582 A1
(43) Pub. Date: Apr. 9, 2026

(54) INTEGRATED CIRCUIT WITH P/N GAA TRANSISTORS OF DIFFERENT CHANNEL MATERIALS

(71) Applicant: Taiwan Semiconductor Manufacturing Co., Ltd., Hsinchu (TW)

(72) Inventors: Yi-Bo LIAO, Hsinchu (TW); Yi-Hsun CHIU, Hsinchu (TW); Cheng-Ting CHUNG, Hsinchu (TW)

(73) Assignee: Taiwan Semiconductor Manufacturing Co., Ltd., Hsinchu (TW)

(21) Appl. No.: 19/050,825

(22) Filed: Feb. 11, 2025

Related U.S. Application Data
(60) Provisional application No. 63/703,644, filed on Oct. 4, 2024.

(51) Int. Cl. H10D 84/85; H10D 84/01

(52) U.S. Cl. CPC H10D 84/856; H10D 84/0167; H10D 84/851

(57) ABSTRACT

An integrated circuit includes a substrate and a first transistor of a first conductivity type including a plurality of stacked first channels of a first semiconductor material above the substrate. The integrated circuit includes a second transistor of a second conductivity type opposite the first conductivity type and including a plurality of stacked second channels of a second semiconductor material above the substrate and different from the first semiconductor material.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-31 are cross-sectional views of an integrated circuit at various stages of processing, in accordance with some embodiments.

FIG. 32 is a flow diagram of a method of manufacturing an integrated circuit, in accordance with some embodiments.

FIG. 33 is a flow diagram of a method of manufacturing an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets).

The nanosheet transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanosheet structure.

Embodiments of the present disclosure provide an integrated circuit including N-type transistors having stacked channels of a first semiconductor material and P-type transistors having stacked channels of a second semiconductor material. Initially, a stack of semiconductor layers is formed on a substrate. The stack of semiconductor layers includes alternating layers of the first semiconductor material and the second semiconductor material. The hard mask layer is formed over the stack of semiconductor layers. The stack of semiconductor layers is patterned, using the hard mask layer, to form a plurality of semiconductor fins. The fins are then further patterned to form stacks of first channels from the first semiconductor layers in N-type regions and stacks of second channels from the second semiconductor layers in P-type regions. The hard mask facilitates removal of the second semiconductor layers in the N-type regions. The hard mask facilitates removal of the first semiconductor layers in the P-type regions. The result is that N-type transistors each have a stack of first channels of the first semiconductor material and P-type transistors each have a stack of second channels of the second semiconductor material.

Formation of channels of the first semiconductor material for N-type transistors and channels of the second semiconductor material for P-type transistors provides various benefits. The first semiconductor material provides higher charge carrier mobility for N-type transistors, while the second semiconductor material provides higher charge carrier mobility for P-type transistors. This results in higher overall channel conductivities in the on-state for both types of devices. This further results in better functioning integrated circuits and electronic devices in which the integrated circuits are installed.

While the figures and description focus primarily on examples in which the transistors are nanostructure transistors including stacks of channels, principles of the present disclosure extend to other types of transistors. Principles of the present disclosure extend to MOS transistors, FinFET transistors and other types of transistors.

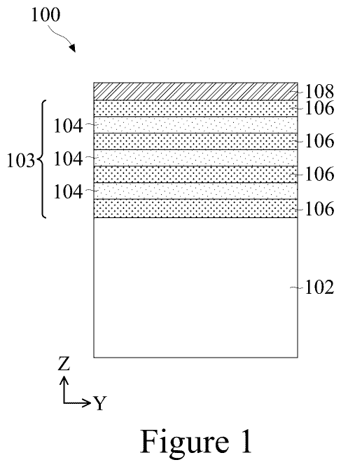

FIGS. 1-29 are cross-sectional views of an integrated circuit 100 fabricated in accordance with some embodiments of the present disclosure. The fabrication process results in a plurality of transistors, as will be described in further detail below.

FIG. 1 is a cross-sectional view of the integrated circuit 100 at an intermediate stage of processing. The integrated circuit 100 includes a substrate 102. In some embodiments, the substrate 102 is a semiconductor substrate, such as a bulk semiconductor, or the like, which may be doped (e.g., with a P-type or an N-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and semiconductor layers 106 alternating (i.e., interleaved) with each other. In the example of FIG. 1 the stack 103 includes three semiconductor layers 104 and three semiconductor layers 106. However, in practice, different numbers of semiconductor layers 104 and semiconductor layers 106 can be utilized without departing from the scope of the present disclosure.

As will be set forth in further detail below, the semiconductor layers 104 will be patterned to form stacked channels of a plurality of transistors of a first conductivity type in a first region of the integrated circuit 100. The semiconductor layers 106 will be patterned to form channels of a plurality of transistors of a second conductivity type in a second region of the integrated circuit 100. As set forth in more detail below, at the first region of the integrated circuit 100 the semiconductor layers 106 will eventually be entirely removed and are utilized to enable forming gate metals and other structures around the channels of the first transistors. As set forth in more detail below, at the second region of the integrated circuit 100 the semiconductor layers 104 will eventually be entirely removed and are utilized to enable forming gate metals and other structures around the channels of the second transistors.

In some embodiments, the semiconductor layers 104 may be formed of a first semiconductor material suitable, such as silicon, silicon carbide, or the like, and the semiconductor layers 106 may be formed of a second semiconductor material, such as silicon germanium or the like. Each of the layers of the multi-layer stack 103 may be epitaxially grown using a process such as chemical vapor deposition (CVD), atomic layer deposition (ALD), vapor phase epitaxy (VPE), molecular beam epitaxy (MBE), or the like.

Due to high etch selectivity between the materials of the semiconductor layers 104 and the semiconductor layers 106, the semiconductor layers 106 of the second semiconductor material may be removed at the first area without significantly etching the semiconductor layers 104 of the first semiconductor material, thereby allowing the semiconductor layers 104 to be released to form stacked channel regions of the first transistors, as will be set forth in more detail below. Due to high etch selectivity between the materials of the semiconductor layers 104 and the semiconductor layers 106, the semiconductor layers 104 of the second semiconductor material may be removed at the second area without significantly etching the semiconductor layers 106 of the first semiconductor material, thereby allowing the semiconductor layers 106 to be released to form stacked channel regions of the second transistors, as will be set forth in more detail below.

In one example, the semiconductor layers 104 are silicon and the semiconductor layers 106 are silicon germanium. In some embodiments, the semiconductor layers 106 have a concentration of germanium between 10% and 50%, though other concentrations can be utilized without departing from the scope of the present disclosure. This enables the semiconductor layers 106 to be selectively etchable with respect to the semiconductor layers 104. Other materials and concentrations can be utilized without departing from the scope of the present disclosure.

A hard mask layer 108 has been formed on the top of the stack 103, in accordance with some embodiments. The hard mask layer 108 will be patterned to enable protection of underlying channels, as will be described in more detail below. The hard mask layer 108 can include SiO, SiN, SiON, SiCN, SiOCN, SiOC, Al2O3, HfO2, ZrO2, SiC, or other suitable materials.

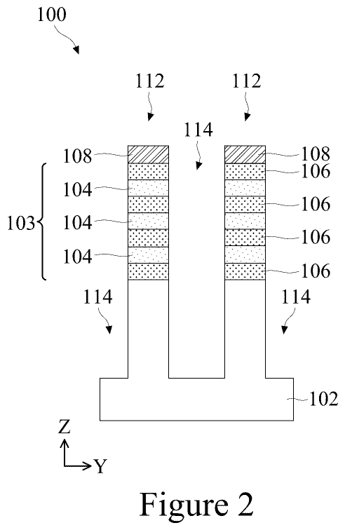

In FIG. 2, a plurality of semiconductor fins 112 have been formed from the stack 103. The semiconductor fins 112 are formed by the hard mask layer 108 and then using the hard mask layer 108 as a mask to form trenches 114 in the stack 103 and in the substrate 102. The trenches 114 can be formed with an anisotropic etching process that etches in the downward direction in the presence of the patterned hard mask layer 108. The etching process defines semiconductor fins 112 by forming trenches 114 through the semiconductor layers 106, the semiconductor layers 104, and the substrate 102.

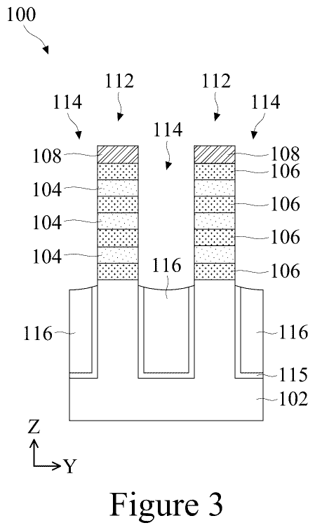

In FIG. 3, a dielectric liner layer 115 has been formed on sidewalls and the bottom of the trenches 114. The dielectric liner layer can include SiO, SiN, SiON, SiCN, SiOC, SiOCN or other suitable dielectric materials. The dielectric liner layer 115 is deposited by chemical vapor deposition (CVD), atomic layer deposition (ALD), physical vapor deposition (PVD), or other suitable deposition processes. In some embodiments, the dielectric liner layer 115 is omitted.

In FIG. 3, shallow trench isolation regions 116 have been formed by depositing a dielectric material in the trenches 114 between fins 112. FIG. 3 illustrates the shallow trench isolation regions 116 as a single layer material. The shallow trench isolation regions 116 may be deposited by CVD, ALD, PVD, or other suitable deposition processes. In an exemplary embodiment, the dielectric material includes silicon oxide. However, the dielectric material can include SIN, SiCN, SiOC, SiOCN, or other dielectric materials without departing from the scope of the present disclosure.

After deposition of the dielectric material of the trench isolation region 116, an etch-back process has been performed to recess the top of the shallow trench isolation regions 116 below the lowest semiconductor layers 106. This results in the shallow trench isolation regions 116 having a top surface that is lower than the bottom surface of the lowest semiconductor layer 106 of each fin. Other processes can be utilized to form the shallow trench isolation regions 116 without departing from the scope of the present disclosure.

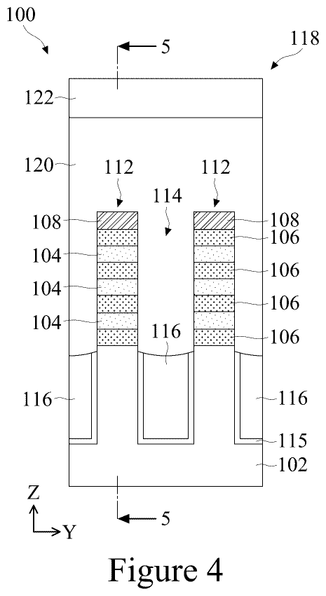

In FIG. 4, a plurality of sacrificial gate structures 118 have been formed, in accordance with some embodiments. While the semiconductor fins 112 extend in the X direction, the sacrificial gate structures 118 extend in the Y direction, perpendicular to the semiconductor fins 112. Initially, each sacrificial gate structure 118 crosses a plurality of semiconductor fins 112 and extends into the trenches 114 between the semiconductor fins 112. While FIG. 4 illustrates only a single sacrificial gate structure 118, in practice, a plurality of sacrificial gate structures 118 are formed extending parallel to each other in the Y direction and spaced apart from each other in the X direction.

The sacrificial gate structures 118 include a sacrificial gate layer 120. The sacrificial gate layer 120 can include materials that have a high etch selectivity with respect to the trench isolation regions 116. In an exemplary embodiment, sacrificial gate layer 120 includes polysilicon. However, the sacrificial gate layer 120 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 120 may be deposited by physical vapor deposition (PVD), CVD, sputter deposition, or other techniques for depositing the selected material.

The sacrificial gate structures 118 include a dielectric layer 122 on the sacrificial gate layer 120. The dielectric layer 122 includes SiO, SiN, SiON, SiCN, SiOC, SiOCN or other suitable dielectric materials. The dielectric layer 122 can be formed by CVD, ALD, PVD, or other suitable deposition processes. In some embodiments, the dielectric layer 122 is omitted.

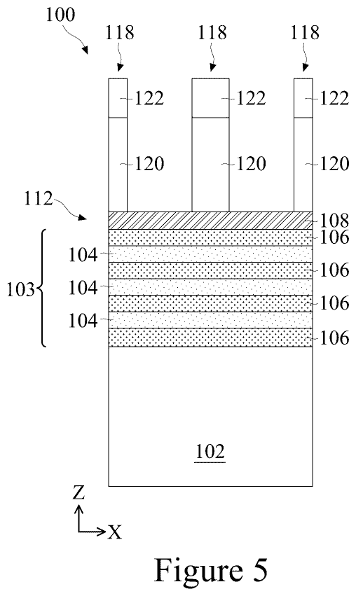

FIG. 5 is an X-view of the integrated circuit 100, in accordance with some embodiments. The view of FIG. 5 corresponds to a cross-sectional view of the integrated circuit 100 at the stage of processing of FIG. 4 taken along cut lines 5, in accordance with some embodiments. FIG. 5 illustrates three sacrificial gate structures 118 on a semiconductor fin 112.

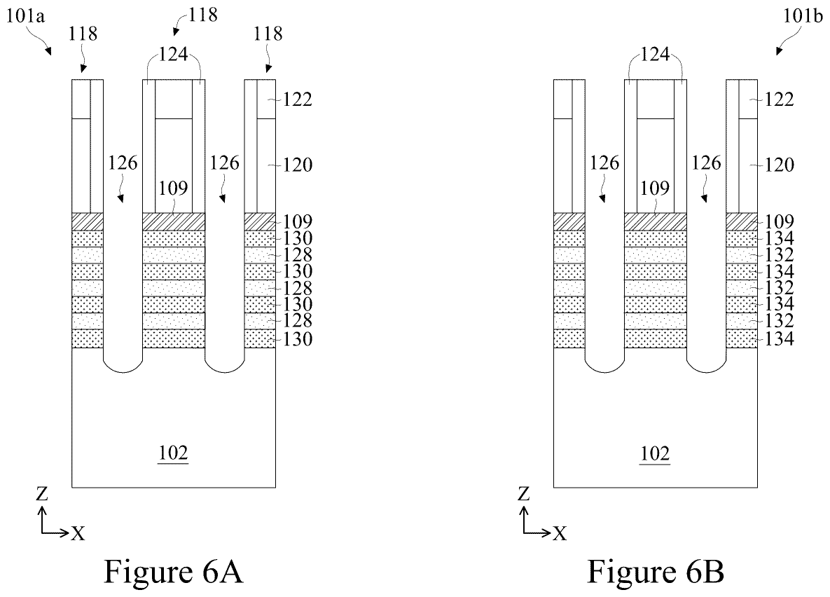

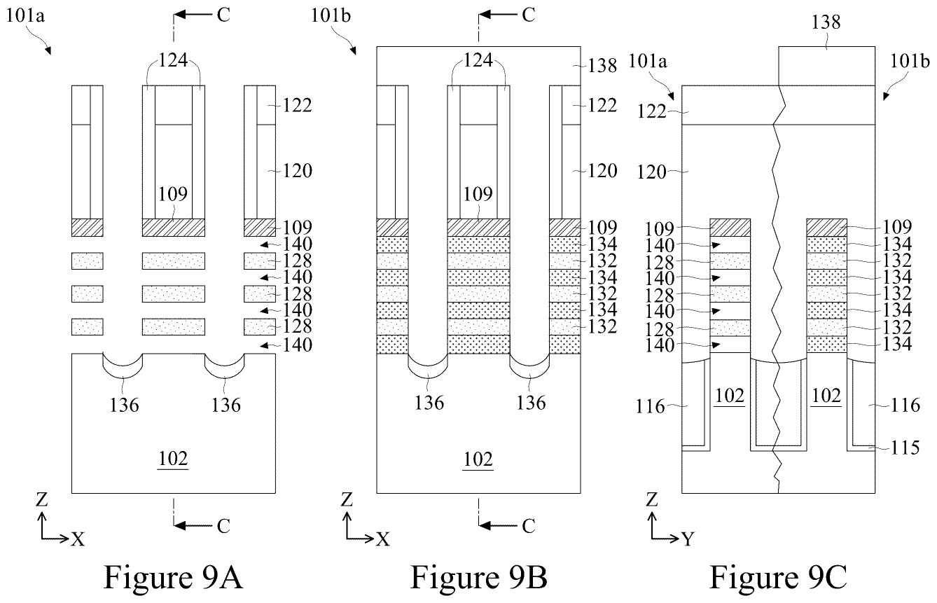

FIG. 6A is a cross-sectional view of a first region 101a of the integrated circuit 100, in accordance with some embodiments. FIG. 6B is a cross-sectional view of a second region 101b of the integrated circuit 100, in accordance with some embodiments. In some embodiments, the first region 10 one a corresponds to a region at which first transistors of a first conductivity type will be formed. The second region 101B corresponds to a region at which second transistors of a second conductivity type will be formed. The subsequent description is primarily directed to embodiments in which N-type transistors are formed at the first region 10 one a, while P-type transistors are formed at the region 101B. However, in some embodiments P-type transistors are formed at the region 101a and N-type transistors are formed at the region 101b. In some embodiments, transistors of a same conductivity type are formed at both regions 101a and 101b. In FIGS. 6A and 6B, and subsequently, Figures with suffix “A” correspond to X-views of the first region 101a, while Figures with suffix “B” correspond to X-views of the second region 101b. Figures with suffix “C” (for example, FIG. 9C) correspond to a hybrid Y-view of both the region 101a and the region 101b.

In FIGS. 6A and 6B, a gate spacer layer 124 has been formed on sidewalls of the sacrificial gate structures 118. In some embodiments, the gate spacer layer 124 is deposited utilizing CVD, ALD, PVD, or other suitable deposition processes. The gate spacer layer 124 includes one or more of SiO, SiN, SiON, SiCN, SiOCN, SiOC, or other suitable dielectric materials. While FIGS. 6A and 6B illustrate only a single gate spacer layer 124, in practice, multiple gate spacer layers may be present on sidewalls of the sacrificial gate structures 118.

In FIGS. 6A and 6B, source/drain trenches 126 have been formed, in accordance with some embodiments. After patterning of the gate spacer layer 124, one or more etching processes are performed to form source/drain trenches 126 in the fins 112. Forming the source/drain trenches 126 includes etching through each of the semiconductor layers 104, each of the semiconductor layers 106, and a portion of the substrate 102. Accordingly, the removal operations may include suitable etch operations for removing materials of the semiconductor layers 104, the semiconductor layers 106, and the substrate 102. The etching processes can include reactive ion etching (RIE), neutral beam etching (NBE), atomic layer etching (ALE), or the like.

Formation of the source/drain trenches 126 results in formation of stacks of channels 128 at the region 101a. In particular, the remaining portions of the semiconductor layers 104 after formation of the source/drain trenches 126 now correspond to stacked channels 128 of transistors at the region 101a. In the example of FIG. 6A, each stack includes three stacked channels 128 of a single transistor. Formation of the source/drain trenches 126 results in formation of a plurality of sacrificial semiconductor nanostructures 130 from the semiconductor layers 106 at the regions 101a.

Formation of the source/drain trenches 126 results in formation of stacks of channels 134 at the region 101b. In particular, the remaining portions of the semiconductor layers 106, after formation of the source/drain trenches 126, now correspond to stacked channels 134 of transistors at the region 101b. In the example of FIG. 6B, each stack includes three stacked channels 134 of a single transistor. As will be described in more detail below, in some embodiments, the remnants of the lowest semiconductor layer 106 at the region 101b will not be utilized as a channel in the stack. Formation of the source/drain trenches 126 results in formation of a plurality of sacrificial semiconductor nanostructures 132 from the semiconductor layers 104 at the regions 101b.

Formation of the source/drain trenches 126 results in a hard mask structure 109 formed from the hard mask layer 108 on top of each stack of channels 128 and 134, in accordance with some embodiments. The hard mask structures 109 have a same width in the X direction as the channels 128 or 134 of a corresponding stack. At the region 101a, the hard mask structure 109 is separated from the highest channel 128 by the highest sacrificial semiconductor nanostructure 130. At the region 101b, the hard mask structure 109 is in direct contact with a top surface of the highest channel 134.

In some embodiments, the channels 128 and 134 have a vertical thickness between 3 nm and 10 nm. In some embodiments, the channels 128 and 134 have a width in the X direction between 10 nm and 80 nm. In some embodiments, the hardmask structures 109 have a vertical thickness between 3 nm and 15 nm. Other dimensions can be utilized without departing from the scope of the present disclosure.

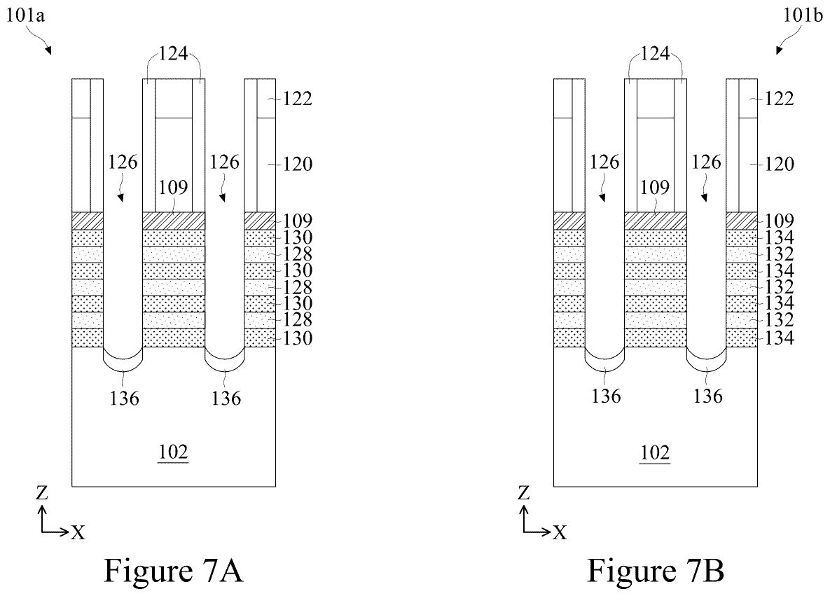

In FIGS. 7A and 7B, bottom dielectric structures 136 have been formed at the bottom of the source/drain trenches 126 at both the N-type regions 101a and the P-type region 101b, in accordance with some embodiments. The bottom dielectric structures 136 can be formed by depositing a dielectric layer on sidewalls of the source/drain trenches 126 and at the bottom of the source/drain trenches 126. The dielectric layer is thicker at the bottom of the trenches. Subsequently, a timed isotropic etching process may be performed to etch the dielectric layer. Because the dielectric layers thicker at the bottom of the source/drain trenches 126, a portion of the dielectric layer remains at the bottom of the trenches as the bottom dielectric structures 136, while the dielectric layers entirely removed from sidewalls of the source/drain trenches 126. The bottom dielectric structures 136 include one or more of SiO, SiN, SiON, SiCN, SiOCN, SiOC, or other suitable dielectric materials. The bottom dielectric structures 136 protect the substrate 102 during subsequent process steps.

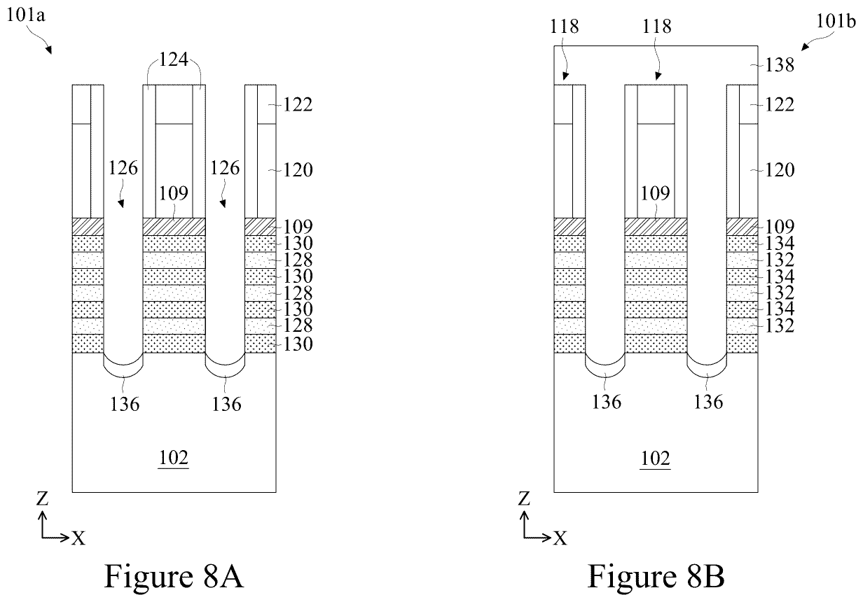

In FIGS. 8A and 8B, a mask material 138 has been deposited and patterned, in accordance with some embodiments. After patterning, the mask material 138 remains at the region 101b and fills the source/drain trenches 126 at the region 101b. After patterning, the mask material 138 is not present at the region 101a. In some embodiments, the mask material 138 is a photoresist that is patterned using traditional photolithography processes. Other materials and processes may be utilized for the mask material 138 without departing from the scope of the present disclosure.

In FIGS. 9A and 9B, an etching process has been performed in the presence of the mask material 138, in accordance with some embodiments. Because the mask material is not present at the region 101a, the etching process completely removes the sacrificial semiconductor nanostructures 130 at the region 101a. Accordingly, the etching process can utilize an etchant that selectively etches the material of the sacrificial semiconductor nanostructures 130 relative to other exposed materials, including the material of the substrate 102 and the channels 128.

Removal of the sacrificial semiconductor nanostructures 130 results in the formation of gaps 140 between adjacent channels 128. Although the channels 134 at the region 101b are the same material as the sacrificial semiconductor nanostructures 130 at the region 101a, the channels 134 are not etched due to the presence of the mask material 138.

FIG. 9C is a hybrid Y-view of both the regions 101a and 101b taken along cut lines C from FIGS. 9A and 9B and juxtaposed next to each other, in accordance with some embodiments. FIG. 9C illustrates the gaps 140 left by removal of the sacrificial semiconductor nanostructures 130 at the region 101a. FIG. 9C illustrates the presence of the mask material 138 and the remaining channels 134 at the region 101b.

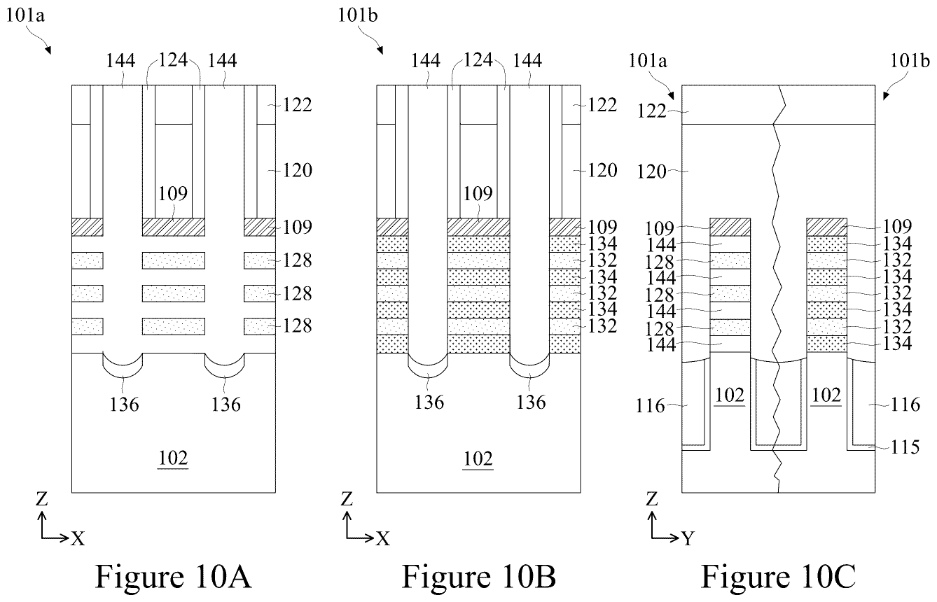

In FIGS. 10A and 10B, the mask material 138 has been removed from the region 101b, in accordance with some embodiments. A dielectric material 144 has been deposited in the source/drain trenches 126 at both the regions 101a and 101b. At the region 101a, the dielectric material 144 fills the gaps 140 left by removal of the sacrificial semiconductor nanostructures 130. The dielectric material 144 includes one or more of SiO, SiN, SiON, SiCN, SiOCN, SiOC, or other suitable dielectric materials. The dielectric material 144 can be deposited by CVD, ALD, or other suitable deposition processes. FIG. 10C is a hybrid Y-view of the regions 101a and 101b.

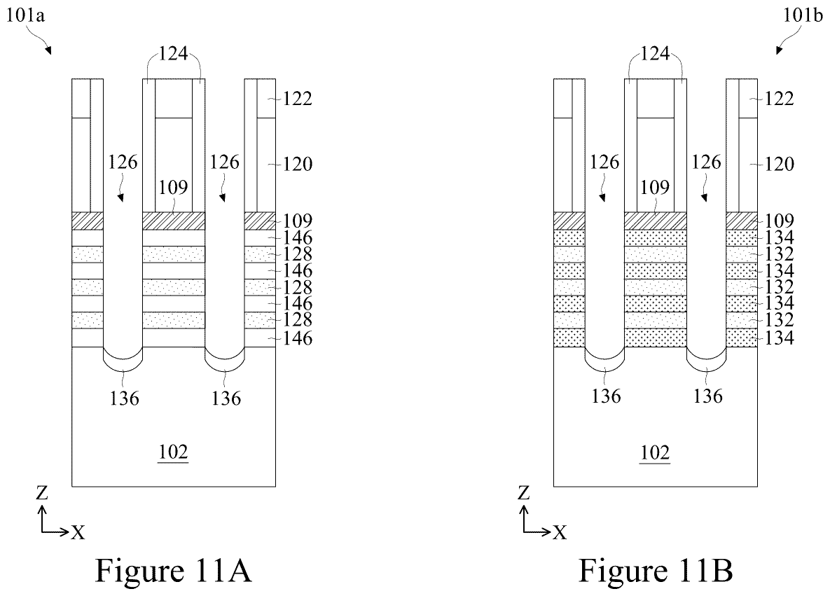

In FIGS. 11A and 11B, the dielectric material 144 has been removed from the source/drain trenches 126 at both the regions 101a and 101b, in accordance with some embodiments. The dielectric material 144 is removed with an anisotropic etching process that selectively etches in the downward direction. The result is that sacrificial dielectric nanostructures 146, corresponding to remnants of the dielectric material 144, remain interleaved with the channels 128 at the region 101a. The sacrificial dielectric nanostructures 146 may also be termed dielectric interposers.

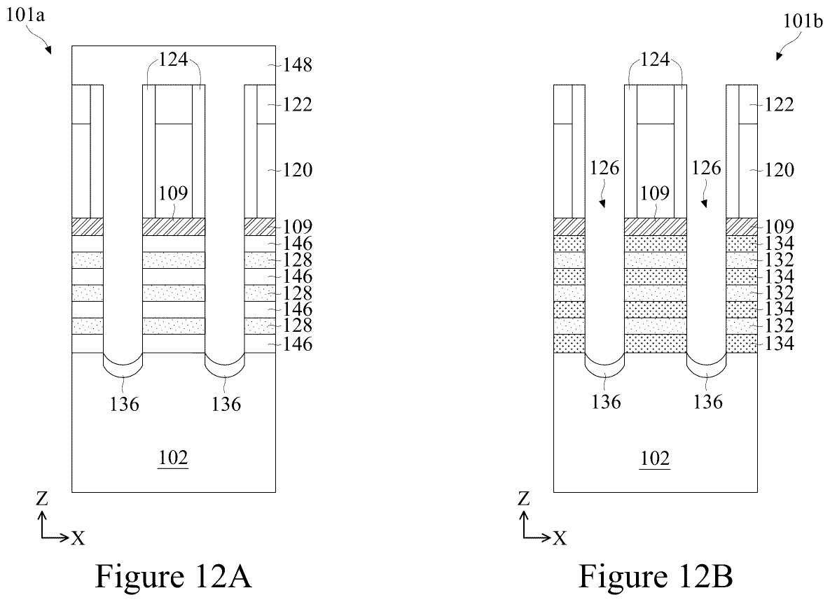

In FIGS. 12A and 12B, a mask material 148 has been deposited and patterned, in accordance with some embodiments. After patterning, the mask material 148 remains at the region 101a and fills the source/drain trenches 126 at the region 101a. After patterning, the mask material 148 is not present at the region 101b. In some embodiments, the mask material 148 is a photoresist that is patterned using traditional photolithography processes. Other materials and processes may be utilized for the mask material 148 without departing from the scope of the present disclosure.

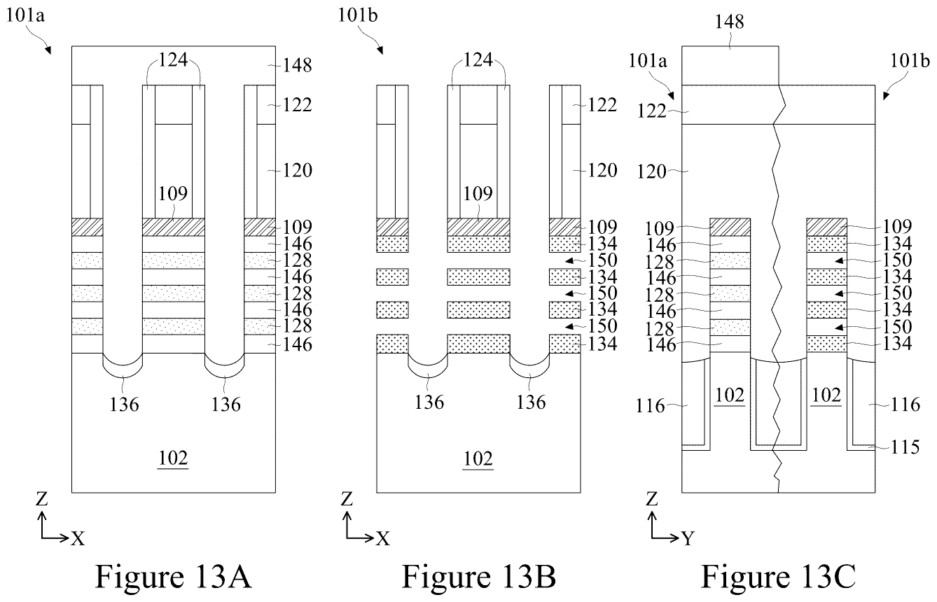

In FIGS. 13A-13C, an etching process has been performed in the presence of the mask material 148, in accordance with some embodiments. Because the mask material 148 is not present at the region 101b, the etching process completely removes the sacrificial semiconductor nanostructures 132 at the region 101b. Accordingly, the etching process can utilize an etchant that selectively etches the material of the sacrificial semiconductor nanostructures 132 relative to other exposed materials, including the material of the channels 134. Removal of the sacrificial semiconductor nanostructures 132 results in the formation of gaps 150 between adjacent channels 134. Although the channels 128 at the region 101a are the same material as the sacrificial semiconductor nanostructures 132 at the region 101b, the channels 128 are not etched due to the presence of the mask material 148.

FIG. 13C illustrates the gaps 150 left by removal of the sacrificial semiconductor nanostructures 132 at the region 101b. FIG. 9C illustrates the presence of the mask material 148 and the remaining channels 128 at the region 101a.

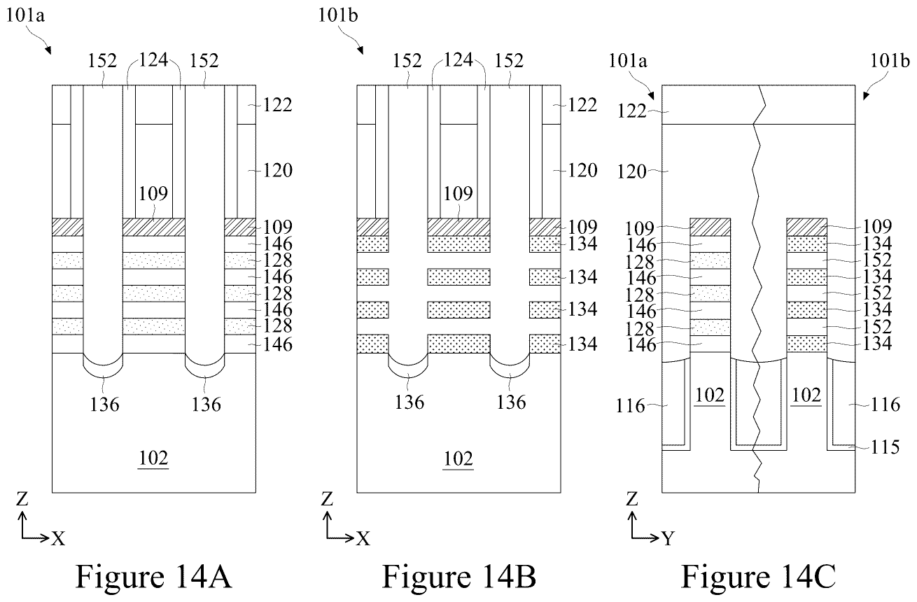

In FIGS. 14A-14C, the mask material 148 has been removed from the region 101a, in accordance with some embodiments. A dielectric material 152 has been deposited in the source/drain trenches 126 at both the regions 101a and 101b. At the region 101b, the dielectric material 152 fills the gaps 150 left by removal of the sacrificial semiconductor nanostructures 132. The dielectric material 152 includes one or more of SiO, SiN, SiON, SiCN, SiOCN, SiOC, or other suitable dielectric materials. The dielectric material 152 can be deposited by CVD, ALD, or other suitable deposition processes.

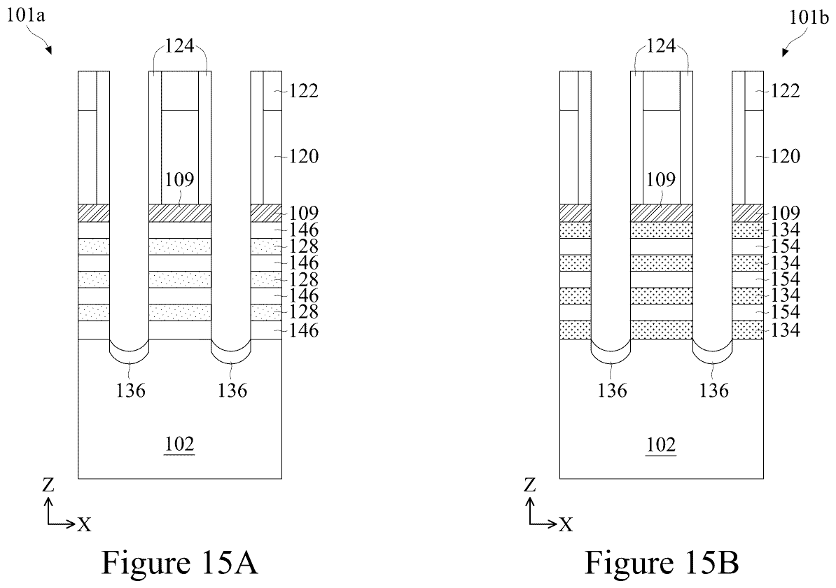

In FIGS. 15A and 15B, the dielectric material 152 has been removed from the source/drain trenches 126 at both the regions 101a and 101b, in accordance with some embodiments. The dielectric material 152 is removed with an anisotropic etching process that selectively etches in the downward direction. The result is that sacrificial dielectric nanostructures 154, corresponding to remnants of the dielectric material 152, remain interleaved with the channels 134 at the region 101b. The sacrificial dielectric nanostructures 154 may also be termed dielectric interposers.

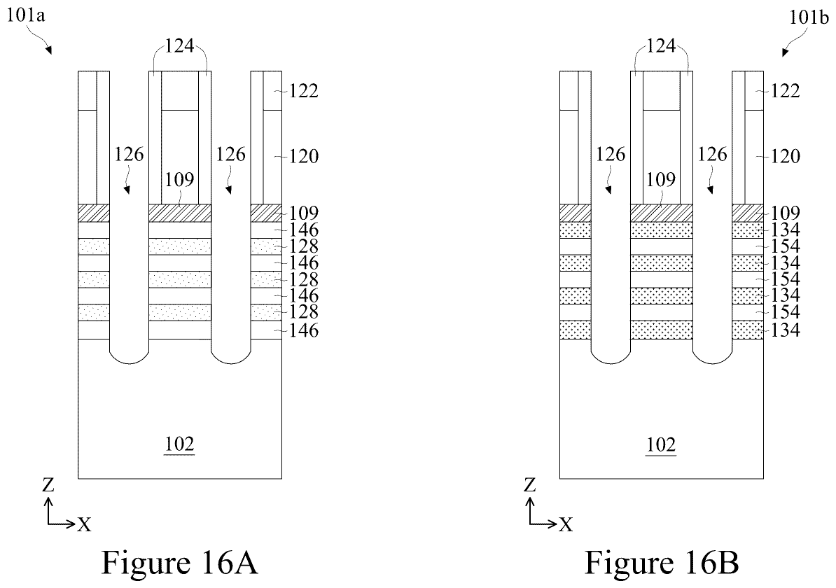

In FIGS. 16A and 16B, the bottom dielectric structures 136 have been removed at both the regions 101a and 101b, in accordance with some embodiments. The bottom dielectric structures 136 are removed via an anisotropic etching process that selectively etches in the downward direction and that selectively etches the material of the bottom dielectric structures 136 relative to the material of the substrate 102. The result is that the substrate 102 is exposed at the bottom of the source/drain trenches 126.

In some embodiments, the bottom dielectric structures 136 are not removed. Source/drain regions are then subsequently formed on the bottom dielectric structures 136. In some embodiments, the bottom dielectric structures are removed at only one of the regions 101a and 101b.

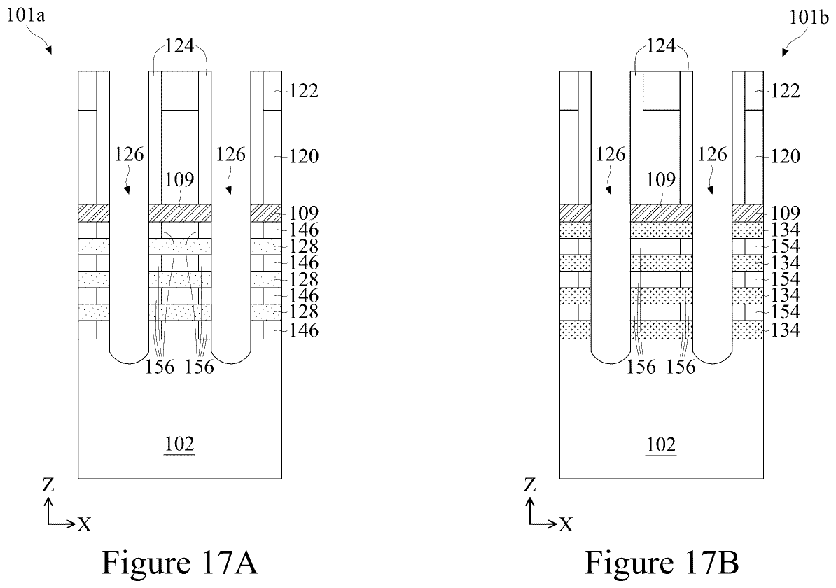

In FIGS. 17A and 17B, one or more selective etching processes are performed to recess exposed end portions of the sacrificial dielectric nanostructures 146 and 154, without substantially etching the channels 128 and 134. More particularly, recesses are formed in the sacrificial dielectric nanostructures 146 between adjacent channels 128 and in the sacrificial dielectric nanostructures 154 between adjacent channels 134. The recesses can be formed by performing an etching process that selectively etches the material of the sacrificial dielectric nanostructures 146 and 154 with respect to the semiconductor materials of the channels 128 and 134.

After formation of the recesses, a dielectric layer is deposited, in accordance with some embodiments. The dielectric layer is deposited on in the source/drain trenches 126 at both the region 101a and 101b. The dielectric layer fills the recesses in the sacrificial semiconductor nanostructures 130 and 132. The dielectric layer is deposited by ALD, CVD, or other suitable deposition processes. In some embodiments, the dielectric layer includes SiCN, SiOCN, SiON, SiN or other suitable dielectric materials.

In FIGS. 17A and 17B, inner spacers 156 have also been formed in the recesses 132. The inner spacers 156 are in contact with ends of the sacrificial semiconductor nanostructures 130 and with the channels 128. As will be set forth in further detail below, the inner spacers 156 separate gate metals from source/drain regions. The inner spacers 156 are formed from the dielectric layer described in the preceding paragraph. In particular, an anisotropic etching process is performed to remove the dielectric layer from the trenches 126. The remaining portion of the dielectric layer corresponds to the inner spacers 156.

There are four pairs of inner spacers 156 at the region 101a. The highest pair of inner spacers 156 at the region 101a are in contact with the hard mask 109 and the highest channel 128. The lowest pair of inner spacers 156 at the region 101a is positioned between the lowest channel 128 and the substrate 102. There are three pairs of inner spacers 156 at the region 101b. The highest pair of inner spacers 156 at the region 101b is not in contact with the hard mask structure 109. The lowest pair of inner spacers 156 at the region 101b is not in contact with the substrate 102.

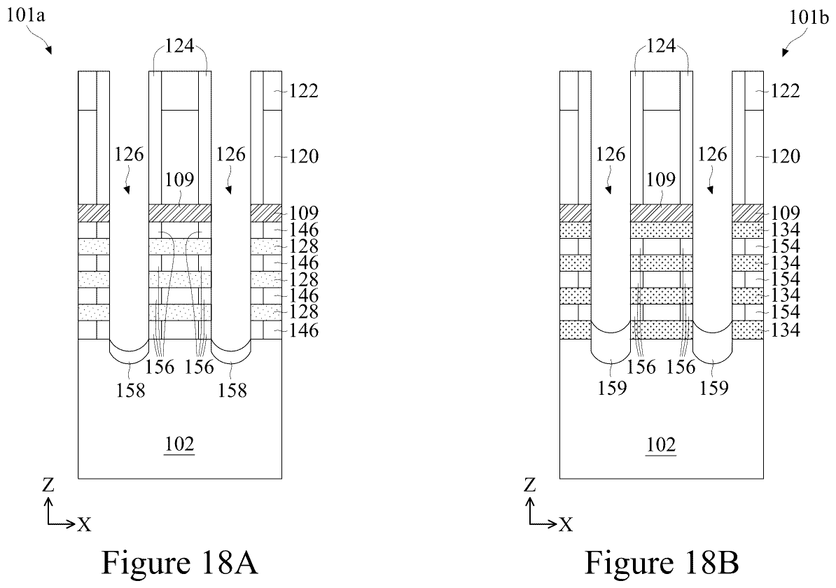

In FIGS. 18A and 18B, bottom semiconductor structures 158 and 159 have been formed in the bottom of the source/drain trenches 126 at the regions 101a and 101b, respectively, in accordance with some embodiments. In particular, the bottom semiconductor structures 158 are formed at the region 101a, while the bottom semiconductor structures 159 are formed at the region 101b. In some embodiments, the bottom semiconductor structures 158 and 159 are silicon or silicon germanium. In some embodiments, the bottom semiconductor structures 158 and 159 or undoped. In some embodiments, the bottom semiconductor structures 159 have a greater vertical thickness than the bottom semiconductor structures 158. In some embodiments, the bottom semiconductor structures 158 have a thickness between 1 nm and 10 nm. In some embodiments, the bottom semiconductor structures 159 have a thickness that is between 5 nm and 10 nm greater than the thickness of the bottom semiconductor structures 158. Other dimensions can be utilized without departing from the scope of the present disclosure.

In some embodiments, the bottom semiconductor structures 158 and 159 are grown in a same epitaxial growth process or different epitaxial growth processes. The growth of the bottom semiconductor structures 158 stops at the bottom of the lowest inner spacers 156 of the region 101a. The growth of the bottom semiconductor structures 159 stops at the bottom of the lowest inner spacers 156 of the region 101b.

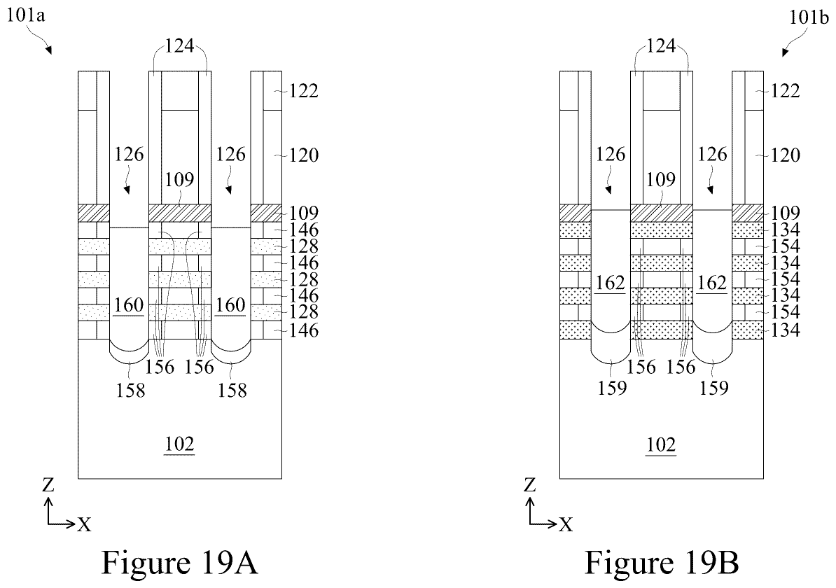

In FIGS. 19A and 19B, source/drain regions 160 have been formed in the source/drain trenches 126 in the region 101a and source/drain regions 162 have been formed in the source/drain trenches 126 in the region 101b, in accordance with some embodiments. The source/drain regions 160 are epitaxially grown from the channels 128. For each stack of channels 128, there are two source/drain regions 160. Some stacks of channels 128 may share a source/drain region 160 with a stack of channels 128 that is adjacent in the X direction.

The source/drain regions 160 and 162 may include any acceptable semiconductor material, such as appropriate for N-type (for source/drain regions 160) or P-type (for source/drain regions 162) devices. For N-type region 101a, the source/drain regions 160 include materials exerting a tensile strain in the channel regions, such as silicon, SiC, SiCP, SiP, or the like, in some embodiments. For P-type region 101b, the source/drain regions 162 include materials exerting a compressive strain in the channel regions, such as SiGe, SiGeB, Ge, GeSn, or the like, in accordance with some embodiments.

In some embodiments, an in-situ doping process may be performed during formation of the source/drain regions 160 to implant to the source/drain regions 160 with N-type dopants. In some embodiments, an in situ doping process may be performed during formation of the source/drain regions 162 to implant the source/drain regions 162 with P-type dopants, depending on the conductivity type of the transistor or region being formed. The N-type dopants can include phosphorus, arsenic, antimony, or other suitable N-type dopants species. The P-type dopants can include boron, gallium, indium, or other suitable P-type dopants species. The source/drain regions 160 and 162 may be implanted with dopants followed by an annealing process. The source/drain regions 160 and 162 may have an impurity concentration of between about 10¹⁹ cm⁻³ and about 10²¹ cm⁻³.

In some embodiments, the source/drain regions 160 have a top surface that is higher than the highest channel 128 and lower than a bottom surface of the hard mask structure 109. In some embodiments, the source/drain regions 162 have a top surface that is higher than a bottom surface of the hard mask structure 109.

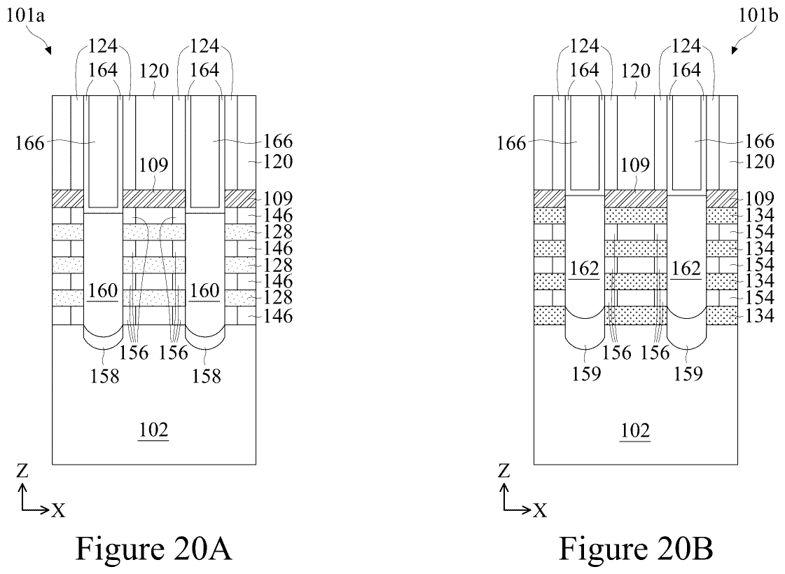

In FIGS. 20A and 20B a contact etch stop layer (CESL) 164 and an interlevel dielectric (ILD) 166 have been formed above the source/drain regions 160 and 162, in accordance with some embodiments. The CESL layer 164 can include a thin dielectric layer conformally deposited on exposed surfaces of the source/drain regions 160 and 162, the gate spacer layers 120, and on other exposed surfaces. The CESL layer 164 can include SiN, SiC, SiOC, SiOCN, SiON, or other suitable dielectric materials. The CESL 164 can be deposited by CVD, ALD, PVD, or other suitable deposition processes.

The interlevel dielectric layer 166 covers the CESL 164. The interlevel dielectric layer 166 fills the remaining spaces between adjacent sacrificial gate structures 118. The interlevel dielectric layer 166 may correspond to a lowest interlevel dielectric layer of the integrated circuit 100. In some embodiments, the interlevel dielectric layer 166 may be termed ILDO. Though not shown herein, additional interlevel dielectric layers may be formed over the interlevel dielectric layer 166. A network of conductive vias and metal lines may be formed in the upper interlevel dielectric layers. The interlevel dielectric layer 166 can include SiO, SiON, SIN, SiC, SiOC, SiOCN, SiON, or other suitable dielectric materials. The interlevel dielectric layer 166 can be deposited by CVD, ALD, PVD, or other suitable deposition processes.

In some embodiments, a CMP process is performed after deposition of the interlevel dielectric layer 166. The result of the CMP process is that the top surfaces of the interlevel dielectric layer 166, the CESL layer 164, the gate spacer layer 124, and the sacrificial gate layer 120 are coplanar. The CMP process may also reduce the height of the sacrificial gate structures 118.

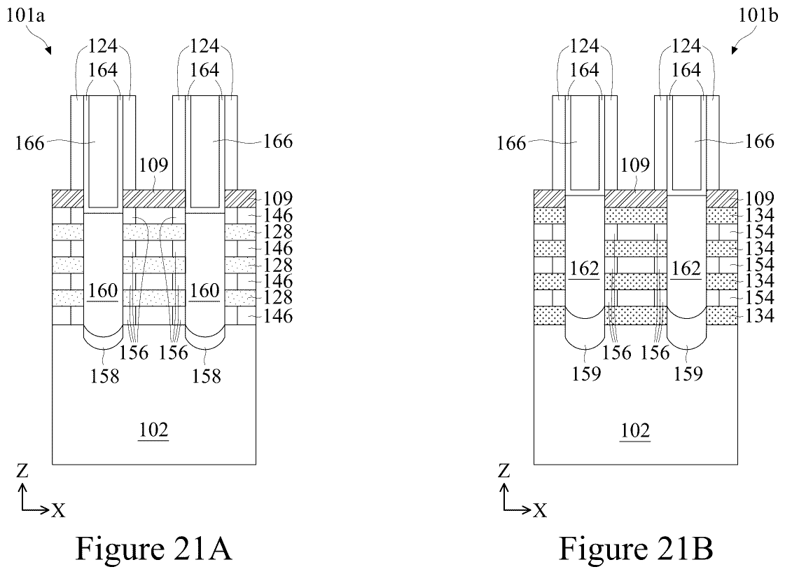

In FIGS. 21A and 21B, the sacrificial gate layer 120 has been removed, in accordance with some embodiments. The sacrificial gate layer 120 can be removed by an etching process that selectively etches the material of the sacrificial gate layer 120 with respect to adjacent materials, such as the CESL layer 164 and the gate spacer layers 124. Removal of the sacrificial gate layer 120 results in gate trenches between the gate spacer layers 124. Removal of the sacrificial gate layer 120 exposes the hard mask structures 109 at the regions 101a and 101b.

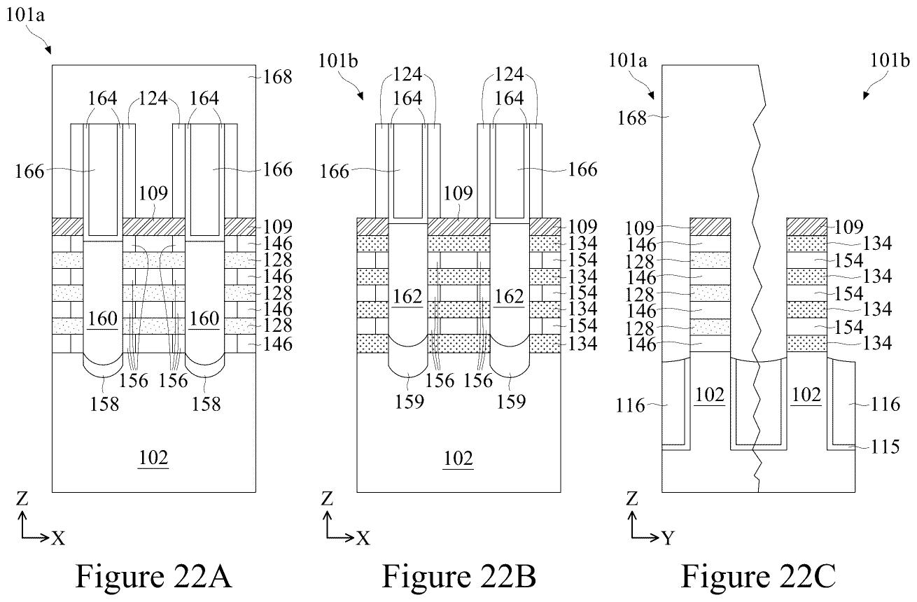

In FIGS. 22A-22C, a mask material 168 has been deposited and patterned, in accordance with some embodiments. After patterning, the mask material 168 covers the region 101a, region 101b is exposed. The mask material 168 can include a photoresist that is patterned using a photolithography process.

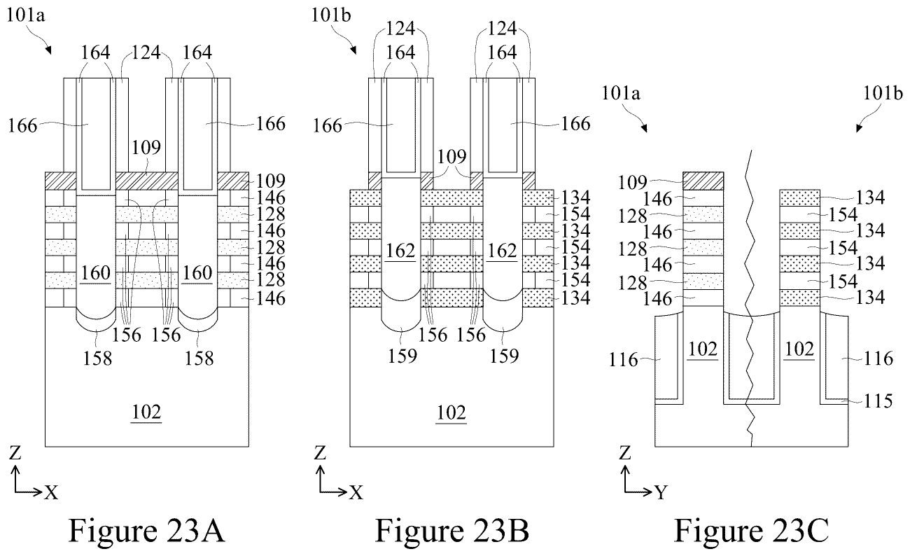

In FIGS. 23A-23C, an etching process has been performed in the presence of the mask material 168, in accordance with some embodiments. The etching process removes the portions of the hard mask structures 109 that are not directly below the gate spacer layers 124 at the region 101b. The result is that the stack of channels 134 is exposed. Remnants of the hard mask structure 109 are present directly below the gate spacer layers 124 at the region 101b. The hard mask structures 109 at the region 101a are not etched due to the presence of the mask material 168. The mask material 168 is then removed.

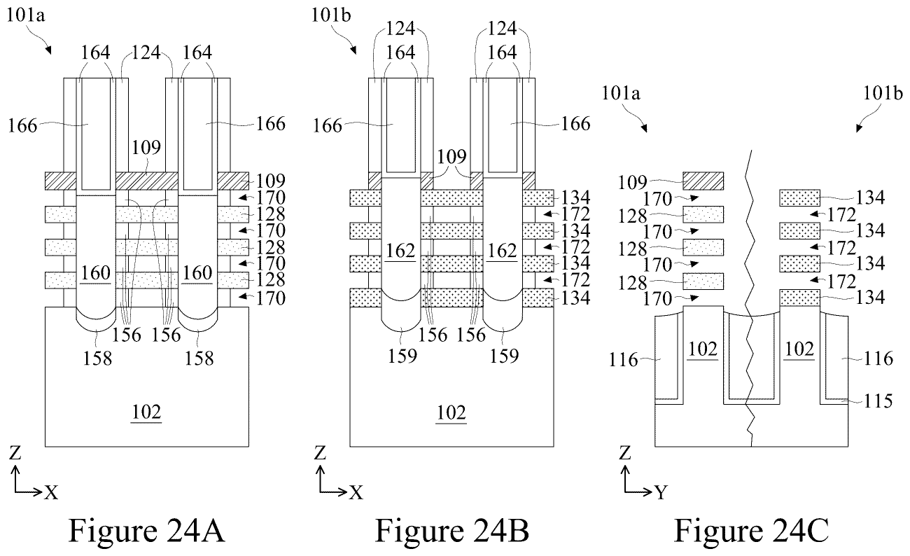

In FIGS. 24A-24C, an etching process has been performed at the regions 101a and 101b, in accordance with some embodiments. The etching process removes the sacrificial dielectric nanostructures 146 at the region 101a and the sacrificial dielectric nanostructures 154 at the region 101b. In some embodiments, the sacrificial dielectric nanostructures 146 and 154 are a same dielectric material. The etching process selectively etches the material of the sacrificial dielectric nanostructures 146 and 154 with respect to the materials of the channels 128 and 134 and the inner spacers 156. The result is that the channels 128 and 134 are released. This enables gate dielectric and gate metal materials can be formed wrapping around the channels 128 and 134. In some embodiments, sacrificial dielectric nanostructures 146 and 154 are removed simultaneously in a same etching process. Removal of the sacrificial dielectric nanostructures 146 and 154 results in gaps 170 at the region 101a and gaps 172 at the region 101b.

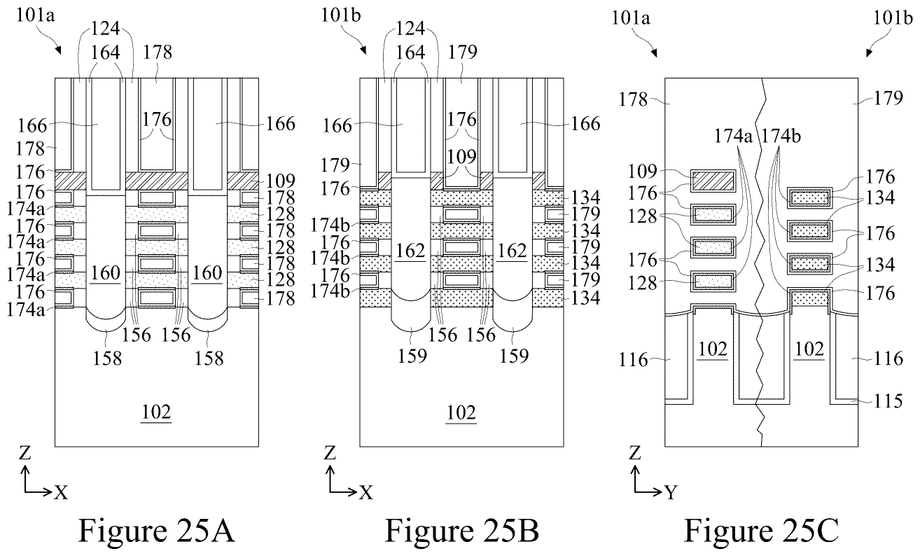

In FIGS. 25A-25C, a gate dielectric has been formed, in accordance with some embodiments. The gate dielectric includes an interfacial gate dielectric layer 174 and a high-K gate dielectric layer 176. The interfacial gate dielectric layer 174 has been deposited on exposed portions of the channels 128 and 134, in accordance with some embodiments. The interfacial gate dielectric layer 174 forms directly on the exposed portions of the channels 128 and 134. The high-K gate dielectric layer 176 forms on the interfacial gate dielectric layer 174 and on other exposed surfaces, such as the exposed sidewalls of the gate spacer layer 124, the exposed surfaces of the hard mask structures 109, and exposed surfaces of trench isolation regions 116.

The interfacial gate dielectric layer 174 is wrapped around the channels 128 and 134. The interfacial gate dielectric layer 174 can include a dielectric material such as silicon oxide, silicon nitride, or other suitable dielectric materials. The interfacial gate dielectric layer 174 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 174 can be formed by a thermal oxidation process, a chemical vapor deposition (CVD) process, or an atomic layer deposition (ALD) process. The interfacial gate dielectric layer 174 can have a thickness between 0.5 nm and 2 nm. Other materials, deposition processes, and thicknesses can be utilized for the interfacial gate dielectric layer 174 without departing from the scope of the present disclosure. In some embodiments, the interfacial dielectric layer 174a of the transistor 101a includes silicon oxide. In some embodiments, the interfacial dielectric layer 174b of the transistor 101b includes an oxide of SiGe.

The high-K gate dielectric layer 176 is deposited in a conformal deposition process. The conformal deposition process deposits the high-K gate dielectric layer 176 on the interfacial gate dielectric layer 174, on the substrate 102, on the trench isolation regions 116, on the gate spacer layer 124, and on the hard mask structures 109. The high-K gate dielectric layer 176 is wrapped around the channels 128. The high-K gate dielectric layer 176 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K gate dielectric layer 176 may be formed by CVD, ALD, or any suitable method. Other thicknesses, deposition processes, and materials can be utilized for the high-K gate dielectric layer 176 without departing from the scope of the present disclosure. The high-K gate dielectric layer 176 is wrapped around the hard mask structures 109 at the region 101. The high-K gate dielectric layer 176 is formed only on exposed vertical sidewalls of the hard mask structures 109 at the region 101b.

In FIGS. 25A-25C, a gate metal 178 has been deposited in the region 101a and a gate metal 179 has been deposited in the region 101b, in accordance with some embodiments. In some embodiments the gate metal 178 and the gate metal 179 are a same gate metal deposited in a same deposition step. In some embodiments the gate metals 178 and 179 can include different gate metals deposited in separate deposition steps, or different combinations of gate metals deposited in separate deposition steps. The gate metal 178 is a gate electrode of the N-type transistor. The gate metal 179 is a gate electrode of the P-type transistor.

The gate metal 178/179 is deposited in place of the sacrificial gate layer 120 and the sacrificial dielectric nanostructures 146 and 154. Accordingly, the gate metal 178 is positioned in the gate trench above the hard mask layer 109 at the region 101a and above the highest channel 134 at the region 101b. The gate metal 178/179 is also wrapped around the channels 128 and 134. The gate metal 178 is also wrapped around the hard mask structure 109 at the regions 101a. The gate metal 178 has a vertical height above the hard mask structure 109 at the region 101a between 6 nm and 10 nm. The gate metal 179 has a vertical height above the highest channel 134 at the region 101b between 6 nm and 70 nm. The top surface of the gate metal 178 at the region 101a is coplanar with the top surface of the gate metal 179 at the region 101b.

In FIGS. 25A-25C, a single gate metal 178/179 is illustrated as the gate electrode of a transistors. However, in practice, the gate metal 178/179 can include multiple gate metals. For example, the gate metal 178/179 can include one or more liner layers, one or more work function layers, and a gate fill material that fills the remaining spaces. The gate metal 178/179 can include one or more of Ti, TiN, Ta, TaN, Al, Cu, Co, Ru, W, Au, or other suitable conductive materials. The gate metal 178/179 can be deposited by PVD, ALD, or CVD. In some embodiments, the gate metal 178 can have a different number of layers than the gate metal 179.

In some embodiments, the gate metal 178/179 is wrapped around the channels 128 and 134 and fills the space between adjacent stacks of channels 128 and 134.

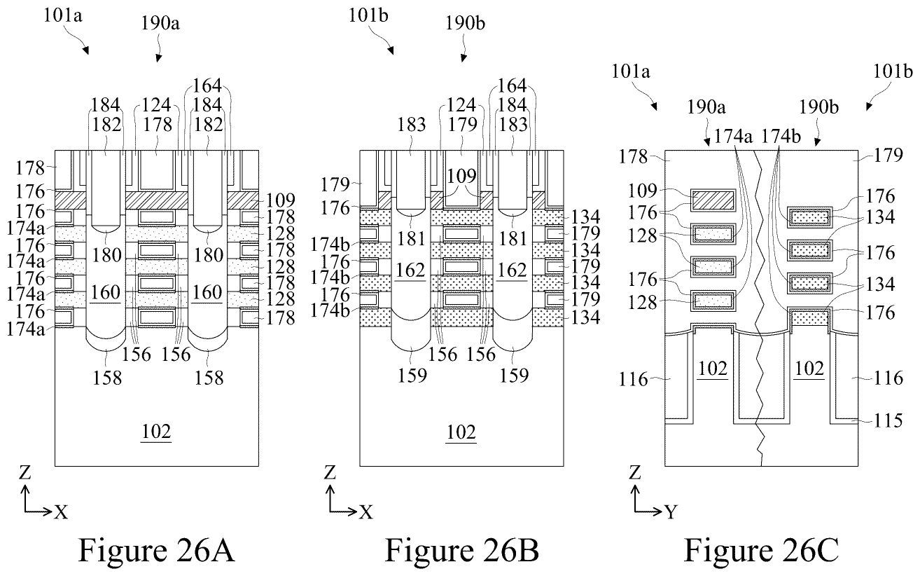

In FIGS. 26A-26C, a silicide 180 is formed on a top surface of the source/drain regions 160 and a silicide 181 is formed on a top surface of the source/drain region 162. The silicides 180/181 can include the same materials formed simultaneously in the same processes or different materials formed in different processes. Formation of the silicide 180/181 can include depositing a metal such as titanium, nickel, tantalum, or other suitable metals. A thermal annealing process is then performed to form the silicide 180/181 from the metal layer and the semiconductor material of the source/drain regions 160 and 162.

Source/drain contacts 182 have been formed on the silicide 180 at the region 101a and source/drain contacts 182 have been formed on the silicide 181 at the region 101b, in accordance with some embodiments. The source/drain contacts 182/183 can include the same materials formed simultaneously the same processes or different materials formed in different processes. The source/drain contacts 182/183 include metals that are electrically connected to the source/drain regions 160 and 162 by the silicides 180/181. The source/drain contacts 182/183 can include W, Al, Au, Ru, Co, Mb, Ta, Ti, TaN, TiN, or other suitable materials. In some embodiments, due to the height differences in the top surfaces of the source/drain regions 162 compared to the source/drain regions 160, the source/drain contacts 182 and 183 have different heights at the regions 101a and 101b. In some embodiments, for the transistors 190a at the region 101a, the source/drain contacts 182 have a vertical thickness between 15 nm and 35 nm. In some embodiments, for the transistors 190b at the region 101b, the source/drain contacts 183 have a vertical thickness between 10 nm and 30 nm. Accordingly, the source/drain contacts 182 at the region 101a is a vertical thickness that is between 5 nm and 10 nm greater than the source/drain contact 183 at the region 101b. In some embodiments, a liner layer 184 is positioned on sidewalls of the source/drain contacts 182/183 at both the regions 101a and 101b.

In FIG. 26A-26C, processing of the transistors 190 is substantially complete, in accordance with some embodiments. In particular N-type transistors 190a have been formed at the region 101a. Each N-type transistor 190a includes a stack of channels 128 extending between source/drain regions 160. One or more gate metals 178 of a gate electrode is wrapped around the channels 128 and separated from the channels 128 by the gate dielectric layers 174 and 176. P-type transistors 190b have been formed at the region 101b. Each P-type transistor 190b includes a stack of channels 134 extending between source/drain regions 162. One or more gate metals 179 of a gate electrode is wrapped around the channels 134 and separated from the channels 134 by the gate dielectric layers 174 and 176.

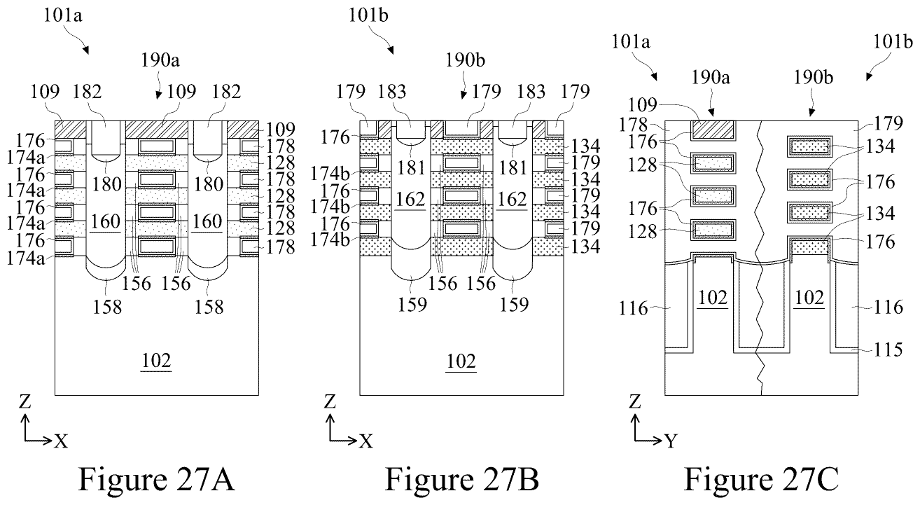

FIGS. 27A-27C illustrate regions 101a and 101b of an integrated circuit 100, in accordance with some embodiments. The integrated circuit of FIGS. 27A-27C is substantially similar to the integrated circuit of FIGS. 26A-26C, except that a CMP process has been performed utilizing the hard mask structure 109 of the region 101a as an etch stop layer. The result is that the gate metal 178 and the source/drain contacts 182 have top surfaces that are substantially coplanar with a top surface of the hard mask structures 109 of the region 101a. This greatly reduces the height of the gate metal 178 and of the source/drain contacts 182. The gate metal 178 has a height between 6 nm and 10 nm at the region 101a. The gate metal 179 has a height between 6 nm and 70 nm at the region 101b.

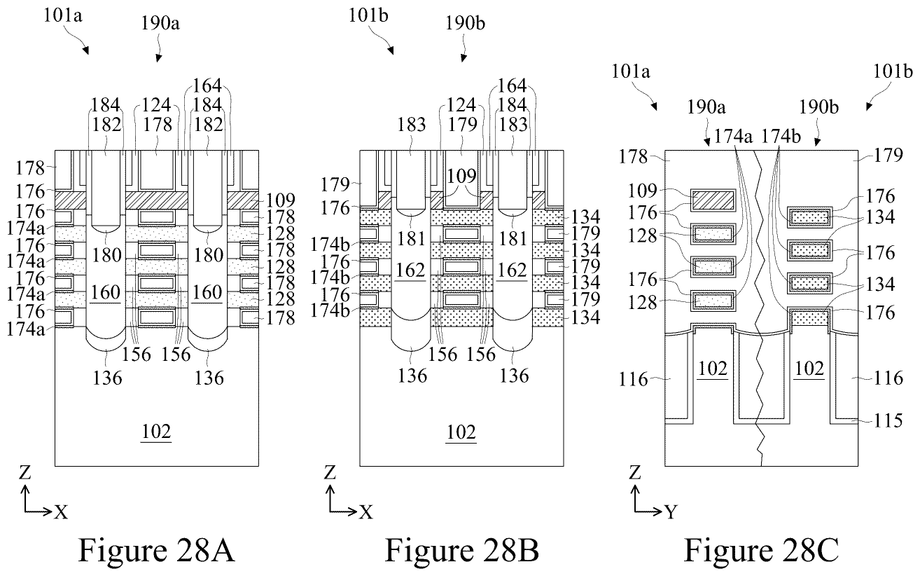

FIGS. 28A-28C illustrate regions 101a and 101b of an integrated circuit 100, in accordance with some embodiments. The integrated circuit of FIGS. 28A-28C is substantially similar to the integrated circuit of FIGS. 26A-26C, except that the bottom dielectric structures 136 are not removed. The bottom dielectric structures 136 of the region 101a have a vertical thickness between 5 nm and 10 nm. The bottom dielectric structures 136 of the region 101b have a vertical thickness between 10 nm and 15 nm.

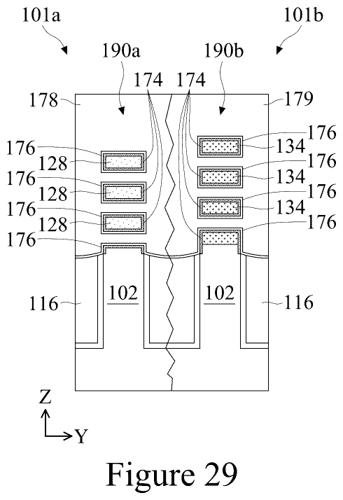

FIG. 29 illustrates regions 101a and 101b of an integrated circuit 100, in accordance with some embodiments. The integrated circuit of FIG. 29 is substantially similar to the integrated circuit of FIGS. 26A-26C, except that the hard mask structure 109 has been removed at the region 101a. Portions of the hard mask structure 109 may remain below the gate spacer layer 124 in a similar manner to the region 101b.

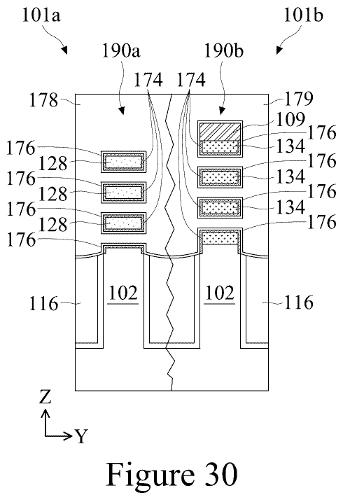

FIG. 30 illustrates regions 101a and 101b of an integrated circuit 100, in accordance with some embodiments. The integrated circuit of FIG. 30 is substantially similar to the integrated circuit of FIG. 29, except that the hard mask structure 109 has not been removed at the region 101b. The result is that the gate metal 179 wraps around the top channel 134 and the hard mask layer 109 jointly. The top surface of the top channel 134 is in direct contact with the bottom surface of the hard mask structure 109 at the region 101b.

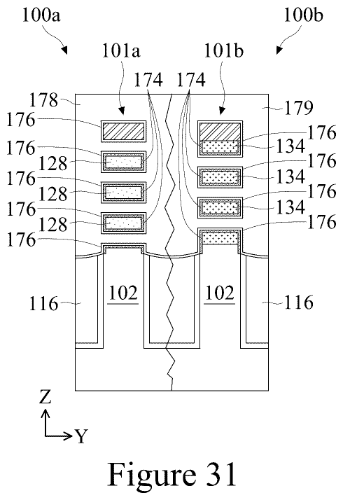

FIG. 31 illustrates regions 101a and 101b of an integrated circuit 100, in accordance with some embodiments. The integrated circuit of FIG. 30 is substantially similar to the integrated circuit of FIG. 30, except that the hard mask structure 109 has not been removed at the region 101a.

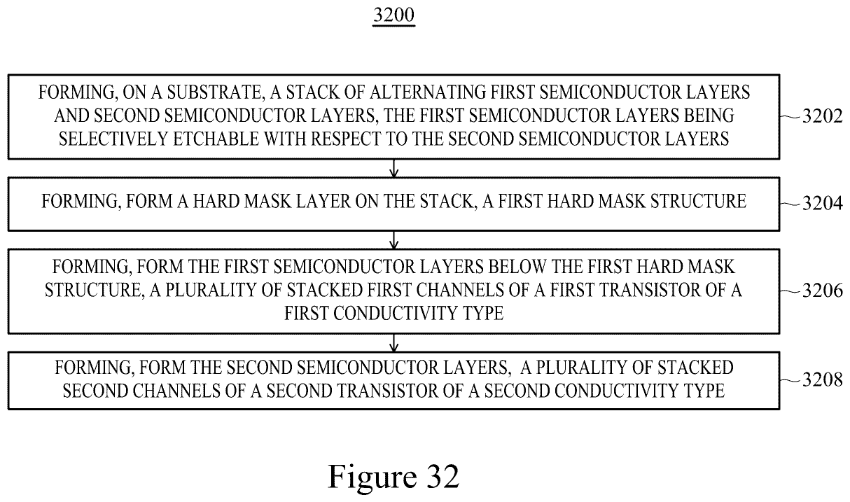

FIG. 32 is a flow diagram of a method 3200 for forming an integrated circuit, in accordance with some embodiments. The method 3200 can utilize the structures, processes, and systems described in relation to FIGS. 1-31. At 3202, the method 3200 includes forming, on a substrate, a stack of alternating first semiconductor layers and second semiconductor layers, the first semiconductor layers being selectively etchable with respect to the second semiconductor layers. One example of a stack is the stack 103 of FIG. 1. One example of first semiconductor layers are the semiconductor layers 104 of FIG. 1. One example of second semiconductor layers are the semiconductor layers 106 of Figure one. At 3204, the method 3200 includes forming, from a hard mask layer on the stack, a first hard mask structure. One example of a first hard mask layer is the hard mask layer 108 of FIG. 1. One example of a first hard mask structure is the hard mask structure 109 of FIG. 6A. At 3206, the method 3200 includes forming, from the first semiconductor layers below the first hard mask structure, a plurality of stacked first channels of a first transistor of a first conductivity type. One example of first channels are the channels 128 of FIG. 6A. At 3208, the method 3200 includes forming, from the second semiconductor layers, a plurality of stacked second channels of a second transistor of a second conductivity type. One example of second channels 134 of FIG. 6B.

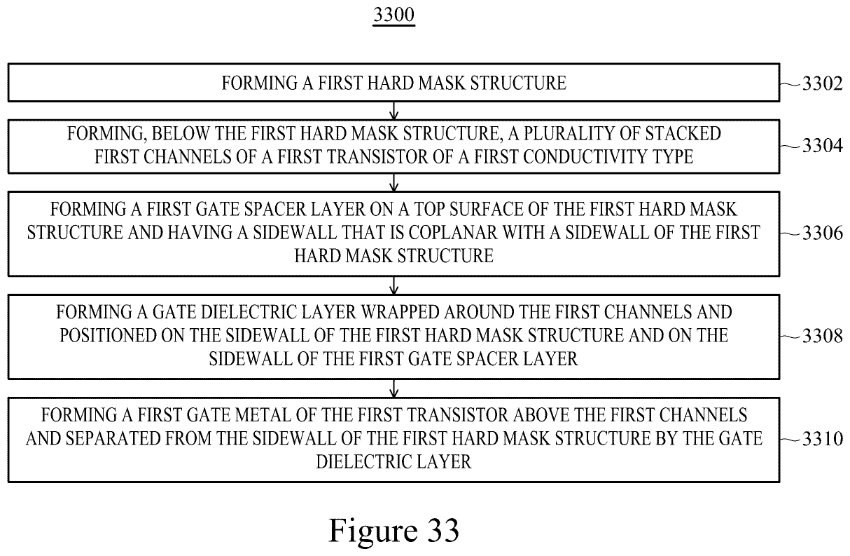

FIG. 33 is a flow diagram of a method 3300 for forming an integrated circuit, in accordance with some embodiments. The method 3300 can utilize the structures, processes, and systems described in relation to FIGS. 1-31. At 3302, the method 3300 includes forming a first hard mask structure. One example of a first hard mask structure is the hard mask structure 109 of FIG. 25B. At 3304, the method 3300 includes forming, below the first hard mask structure, a plurality of stacked first channels of a first transistor of a first conductivity type. A first channels are the channels 134 of FIG. 25B. At 3306, the method 3300 includes forming a first gate spacer layer on a top surface of the first hard mask structure and having a sidewall that is coplanar with a sidewall of the first hard mask structure. One example of a first gate spacer layer is the gate spacer layer 124 of FIG. 25B. At 3308, the method 3300 includes forming a gate dielectric layer wrapped around the first channels and positioned on the sidewall of the first hard mask structure and on the sidewall of the first gate spacer layer. Of example of a gate dielectric layer is the gate dielectric layer 176 of FIG. 25B. At 3310, the method 3300 includes forming a first gate metal of the first transistor above the first channels and separated from the sidewall of the first hard mask structure by the gate dielectric layer. One example of a first gate metal is the gate metal 179 of FIG. 25B.

Embodiments of the present disclosure provide an integrated circuit including N-type transistors having stacked channels of a first semiconductor material and P-type transistors having stacked channels of a second semiconductor material. Initially, a stack of semiconductor layers is formed on a substrate. The stack of semiconductor layers includes alternating layers of the first semiconductor material and the second semiconductor material. The hard mask layer is formed over the stack of semiconductor layers. The stack of semiconductor layers is patterned, using the hard mask layer, to form a plurality of semiconductor fins. The fins are then further patterned to form stacks of first channels from the first semiconductor layers in N-type regions and stacks of second channels from the second semiconductor layers in P-type regions. The hard mask facilitates removal of the second semiconductor layers in the N-type regions. The hard mask facilitates removal of the first semiconductor layers in the P-type regions. The result is that N-type transistors each have a stack of first channels of the first semiconductor material and P-type transistors each have a stack of second channels of the second semiconductor material.

Formation of channels of the first semiconductor material for N-type transistors and channels of the second semiconductor material for P-type transistors provides various benefits. The first semiconductor material provides higher charge carrier mobility for N-type transistors, while the second semiconductor material provides higher charge carrier mobility for P-type transistors. This results in higher overall channel conductivities in the on-state for both types of devices. This further results in better functioning integrated circuits and electronic devices in which the integrated circuits are installed.

In some embodiments, a device includes a substrate and a first transistor of a first conductivity type including a plurality of stacked first channels of a first semiconductor material above the substrate. The device includes a second transistor of a second conductivity type opposite the first conductivity type and including a plurality of stacked second channels of a second semiconductor material above the substrate and different from the first semiconductor material.

In some embodiments, a method includes forming, on a substrate, a stack of alternating first semiconductor layers and second semiconductor layers. The first semiconductor layers are selectively etchable with respect to the second semiconductor layers. The method includes forming, from a hard mask layer on the stack, a first hard mask structure, forming, from the first semiconductor layers below the first hard mask structure, a plurality of stacked first channels of a first transistor of a first conductivity type, and forming, from the second semiconductor layers, a plurality of stacked second channels of a second transistor of a second conductivity type.

In some embodiments, a method includes forming a first hard mask structure and forming, below the first hard mask structure, a plurality of stacked first channels of a first transistor of a first conductivity type. The method includes forming a first gate spacer layer on a top surface of the first hard mask structure and having a sidewall that is coplanar with a sidewall of the first hard mask structure. The method includes forming a gate dielectric layer wrapped around the first channels and positioned on the sidewall of the first hard mask structure and on the sidewall of the first gate spacer layer and forming a first gate metal of the first transistor above the first channels and separated from the sidewall of the first hard mask structure by the gate dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate;
a first transistor of a first conductivity type including a plurality of stacked first channels of a first semiconductor material above the substrate; and
a second transistor of a second conductivity type opposite the first conductivity type and including a plurality of stacked second channels of a second semiconductor material above the substrate and different from the first semiconductor material.

2. The device of claim 1, wherein the first transistor includes a first gate metal wrapped around the first channels, wherein the second transistor includes a second gate metal and the second channels.

3. The device of claim 2, wherein the first transistor includes:
a first hard mask structure above the first channels; and
a first gate spacer layer in contact with a top surface of the first hard mask structure, wherein the first gate metal is wrapped around the first hard mask structure.

4. The device of claim 3, wherein the second transistor includes:
a second hard mask structure in contact with a top surface of a highest second channel of the plurality of stacked second channels; and
a second gate spacer layer in contact with a top surface of the second hard mask structure.

5. The device of claim 4, wherein the first transistor includes a first gate dielectric layer wrapped around the first channels and the first hard mask structure, wherein the second transistor includes a second gate dielectric layer wrapped around the second channels and positioned on a sidewall of the second hard mask structure.

6. The device of claim 5, wherein the second gate dielectric layer is positioned between the sidewall of the second gate metal above the second channels.

7. The device of claim 3, wherein a top surface of the first gate metal is coplanar with a top surface of the first hard mask structure.

8. The device of claim 1, wherein:
the first transistor includes:
a first source/drain region above the substrate and coupled to the first channels; and
a first source/drain contact on the first source drain region and having a first height;
the second transistor includes:
a second source/drain region above the substrate and coupled to the second channels; and
a second source/drain contact on the second source drain region and having a second height less than the first height.

9. The device of claim 8, wherein:
the first transistor includes a first bottom semiconductor structure positioned between the substrate and the first source/drain region and having a third height; and
the second transistor includes a second bottom semiconductor structure positioned between the substrate and the second source/drain region and having a fourth height greater than the third height.

10. The device of claim 8, wherein:
the first transistor includes a first bottom dielectric structure positioned between the substrate and the first source/drain region and having a third height; and
the second transistor includes a second bottom dielectric structure positioned between the substrate and the second source/drain region and having a fourth height greater than the third height.

11. The device of claim 1, wherein the first conductivity type is N-type and the first semiconductor material is silicon, wherein the second conductivity type is P-type and the second semiconductor material is silicon germanium.

12. A method, comprising:
forming, on a substrate, a stack of alternating first semiconductor layers and second semiconductor layers, the first semiconductor layers being selectively etchable with respect to the second semiconductor layers;
forming, from a hard mask layer on the stack, a first hard mask structure;
forming, from the first semiconductor layers below the first hard mask structure, a plurality of stacked first channels of a first transistor of a first conductivity type; and
forming, from the second semiconductor layers, a plurality of stacked second channels of a second transistor of a second conductivity type.

13. The method of claim 12, comprising:
forming, from the first semiconductor layers, first sacrificial semiconductor nanostructures interleaved with the second channels;
forming, from the second semiconductor layers, second sacrificial semiconductor nanostructures interleaved with the first channels;
removing the first sacrificial semiconductor nanostructures by selectively etching the first sacrificial semiconductor nanostructures with respect to the second channels;
removing the second sacrificial semiconductor nanostructures by selectively etching the second sacrificial semiconductor nanostructures with respect to the first channels;
forming a first gate metal above the first channels and wrapped around the first channels; and
forming a second gate metal above the second channels and wrapped around the second channels.

14. The method of claim 13, comprising:
forming, from the hard mask layer, a second hard mask structure above and forming the second channels below the second hard mask structure;
forming a gate spacer layer on a top surface of the second hard mask structure;
and forming the second gate metal laterally adjacent to the gate spacer layer.

15. The method of claim 14, comprising:
removing, prior to forming the second gate metal, portions of the second hard mask structure outside the gate spacer layer; and
forming the second gate metal laterally adjacent to sidewalls of the second hard mask structure after removing the portions of the second hard mask structure.

16. The method of claim 13, wherein the first gate metal is wrapped around the first hard mask structure.

17. The method of claim 13, comprising:
forming first sacrificial dielectric nanostructures in place of the first sacrificial semiconductor nanostructures prior to forming the second gate metal;
forming second sacrificial dielectric nanostructures in place of the second semiconductor nanostructures prior to forming the first gate metal;
forming inner spacers in place of end portions of the first and second sacrificial dielectric nanostructures;
removing the first and second sacrificial dielectric nanostructures in a same etching process;
forming the first gate metal in place of the second sacrificial dielectric nanostructures; and
forming the second gate metal in place of the first sacrificial dielectric nanostructures.

18. The method of claim 17, comprising forming the first and second gate metals of a same material in a same deposition process.

19. A method, comprising:
forming a first hard mask structure;
forming, below the first hard mask structure, a plurality of stacked first channels of a first transistor of a first conductivity type;
forming a first gate spacer layer on a top surface of the first hard mask structure and having a sidewall that is coplanar with a sidewall of the first hard mask structure;
forming a gate dielectric layer wrapped around the first channels and positioned on the sidewall of the first hard mask structure and on the sidewall of the first gate spacer layer; and
forming a first gate metal of the first transistor above the first channels and separated from the sidewall of the first hard mask structure by the gate dielectric layer.

20. The method of claim 19, comprising:
forming a second hard mask structure;
forming, below the second hard mask structure, a plurality of stacked second channels of a second transistor of a second conductivity type, wherein the first channels are of a first semiconductor material and the second channels are of a second semiconductor material different than the first semiconductor material;
forming a second gate spacer layer on a top surface of the second hard mask structure; and
forming a second gate metal of the second transistor above the second channels.
